(19) United States
(12) Patent Application Publication
(10) Pub. No.: US 2006/0049428 A1
(43) Pub. Date: Mar. 9, 2006

(54) Tft electronic devices and their manufacture

(76) Inventors: Pieter J. Van Der Zaag, Waalre (GB); Nigel D. Young, Redhill (GB); Ian D. French, Hove (GB); Jeffrey A. Chapman, Burgess Hill (GB)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/520,229

(22) PCT Filed: Jun. 25, 2002
(86) PCT No.: PCT/IB03/02883

§ 371 Date: Jan. 3, 2005

(30) Foreign Application Priority Data
Jul. 5, 2002 (GB) 0215566.1
May 1, 2003 (GB) 0309977.7

(51) Int. Cl. H01L 29/76; H01L 29/745

(52) U.S. Cl. 257/213

(57) ABSTRACT

An electronic device (70) comprises a thin film transistor (TFT) (9,59), the TFT including a channel (16) defined in a layer of polycrystalline semiconductor material (10,48). The polycrystalline semiconductor material is produced by crystallising amorphous semiconductor material (2) using metal atoms (6) to promote the crystallisation process. The polycrystalline semiconductor material (10) includes an average concentration of metal atoms in the range 1.3×10¹⁸ to 7.5×10¹⁸ atoms/cm³. This enables polycrystalline semiconductor TFTs to be formed with leakage properties acceptable for use in active matrix displays using a metal induced crystallisation process of duration significantly less that previously thought necessary. Furthermore, this process duration reduction facilitates the reliable fabrication of poly-Si TFTs having bottom gates formed of metal.

This invention relates to electronic devices comprising polycrystalline semiconductor material and methods for manufacturing the material and such devices.

The high carrier mobility of polycrystalline silicon (polysilicon or poly-Si) relative to amorphous silicon (a-Si) makes it an attractive material for use in large area electronic devices such as active matrix liquid crystal displays (AMLCDs), active matrix polymer LED displays (AMPLEDs), solar cells and image sensors. An example of a flat panel active matrix display is described in U.S. Pat. No. 5,130,829, the contents of which are incorporated herein by reference.

For the purposes of this description, the term “amorphous” relates to materials in which the constituent atoms are randomly positioned. The term “polycrystalline” relates to materials which comprise a plurality of monocrystals, a monocrystal having a regular repeating lattice structure of its constituent atoms. This is particularly relevant to poly-Si, which is commonly formed by melting and cooling amorphous silicon. Typical grain sizes for poly-Si lie between 0.1 μm and 5 μm. However, when crystallised under certain conditions, the silicon can have a grain size on a microscopic scale, typically 0-0.5 μm. The term “microcrystalline” relates to crystalline materials having grain sizes on a microscopic scale.

Conventionally, poly-Si films used for example in thin film transistors (TFTs) have been manufactured by solid phase crystallisation (SPC). This involves depositing an a-Si film on an insulating substrate and crystallising the a-Si film by exposing it to a high temperature for a prolonged period of time, that is typically a temperature in excess of 600° C. for up to 24 hours.

As an alternative, U.S. Pat. No. 5,147,826 discloses a lower temperature method of crystallising an a-Si film. The method comprises the steps of depositing a thin film of metal atoms (of nickel, for example) on the a-Si film and annealing the film. The metal stimulates crystal growth at temperatures below 600° C. and also provides more rapid crystal growth than would otherwise occur. For example, a typical anneal using the method of U.S. Pat. No. 5,147,826 might be at around 550° C. for 10 hours. This represents an improvement over prior methods for at least two reasons: first, it enables low cost, low temperature non-alkali glass substrates such as borosilicate to be used which would normally suffer glass compaction and warp at temperatures of 600° C. or more; and secondly, as the anneal duration is reduced, the manufacturing throughput rate is increased and therefore the associated manufacturing cost may be reduced. The contents of U.S. Pat. No. 5,147,826 are incorporated herein by reference. The use of a metal such as nickel in this way is referred to hereinafter as metal induced crystallisation or “MIC”, and the resulting poly-Si material as “MIC poly-Si”.

More recently, the production of poly-Si using a laser annealing process has been developed and widely adopted commercially. However, this process is relatively slow in that a narrow laser beam is gradually scanned across a substrate irradiating each portion of the surface with several shots, non-uniformity of the laser shots may introduce non-uniformity in the poly-Si, and the laser apparatus is also expensive to implement and maintain. The annealing step in the process of U.S. Pat. No. 5,147,826 can be carried out as a relatively simple batch process in a furnace allowing higher throughput.

TFTs manufactured using the techniques of U.S. Pat. No. 5,147,826 have been hampered by the problem of relatively high leakage currents in their “off” state, making them unsuitable for use in applications such as AMLCDs. This flaw leads to inadequate image retention by the AMLCD.

Typically, in an existing poly-Si AMLCD, an acceptable value of the TFT minimum leakage current (that is, the minimum value of its leakage current across its normal operating range of gate voltage) is around 10 pA or lower at a source-drain voltage of 5V. That is, it is undesirable for the TFT off-current to exceed this value during normal operation of the display as otherwise the current leakage will lead to unacceptable degradation of the display output. This threshold may vary somewhat depending on the characteristics of the picture element associated with the TFT. For a TFT with a channel width of say 4 μm, a leakage current of 10 pA equates to 2.5×10⁻¹² A/μm. (It will be appreciated that A/μm in the context of TFTs in this specification means amperes per μm of channel width of a TFT).

The paper entitled “A High-Performance Polycrystalline Silicon Thin-Film Transistor Using Metal-induced Crystallisation with Ni Solution”, Jpn. J. Appl. Phys. Vol. 37 (1998) pp 7193-7197 by Sooyoung Yoon et al discloses further developments in the techniques of U.S. Pat. No. 5,147,826. A 100 nm thick a-Si film on a substrate is crystallised by dipping it in a Ni absorption solution and then annealing the film at 500° C. for 20 hours. The Ni concentration in the resulting poly-Si is 1.2×10¹⁸ atoms/cm³. The off-state leakage current of a TFT with a channel of poly-Si formed using this process was found to be 2.7×10⁻¹¹ A/μm at a drain voltage of 5V, an order of magnitude greater than the threshold referred to above.

It is an object of the present invention to form electronic devices comprising polycrystalline semiconductor material in a more cost effective manner.

The present invention provides a TFT comprising a channel defined in a layer of polycrystalline semiconductor material produced by crystallising amorphous semiconductor material using metal atoms to accelerate the crystallisation process, wherein the polycrystalline semiconductor material includes an average concentration of metal atoms in the range 1.3×10¹⁸ to 7.5×10¹⁸ atoms/cm³. Using this metal concentration, the inventors have been able to make TFTs having improved leakage current characteristics. In particular, the TFTs exhibit a minimum leakage current of around 2.5×10⁻¹² A/μm or less at a source-drain voltage of 5V. A TFT with this property may be suitable for use as a switching element in an AMLCD without the TFT off-state leakage current degrading the display performance to an unacceptable extent.

The inventors have unexpectedly found that the use of metal atoms in the concentration range referred to above enables polycrystalline semiconductor TFTs to be formed with the leakage properties defined above with an annealing process of duration significantly less that previously thought necessary. Whilst an annealing time of 20 hours at a temperature of around 550° C. achieves the desired properties, it has also been realised that the metal concentrations disclosed herein enable this time to be reduced to 10 hours, 8 hours, or even 6 hours or less at a temperature of 600° C. or less. This leads to substantial productivity and efficiency increases in the manufacturing process.

Preferably, the average concentration of metal atoms in the polycrystalline semiconductor material is greater than 1.9×10¹⁸ atoms/cm³ and/or less than 5×10¹⁸ atoms/cm³. More preferably, the average concentration of metal atoms in the polycrystalline semiconductor material is in the range 2 to 3×10¹⁸ atoms/cm³.

In a preferred embodiment, the average concentration of metal atoms is around 2.5×10¹⁸ atoms/cm³.

Preferably, the TFT has a low-doped drain (LDD) structure. This may increase the range of gate voltage over which the minimum leakage current is substantially achieved.

The invention further provides a method of manufacturing such a device including the steps of:
(a) depositing amorphous semiconductor material on a substrate;
(b) adding metal atoms to the semiconductor material at an average concentration therein in the range 1.3×10¹⁸ to 4×10¹⁸ atoms/cm³, the metal atoms being suitable for accelerating the crystallisation of amorphous semiconductor material; and
(c) annealing the amorphous semiconductor material to form polycrystalline semiconductor material.

Furthermore, it has been found that the application of an electric field to a substrate during the annealing step may further accelerate the process, reducing its duration.

It will be appreciated that various metal atoms may be used in the process of the invention. One or more elements selected from the group consisting of Ni, Cr, Co, Pd, Pt, Cu, Ag, Au, In, Sn, Pb, As, and Sb may be employed. More preferably, one or more elements from the group Ni, Co and Pd are used.

References herein to addition of metal atoms include the metal in elemental form or a compound including atoms of the metal.

Ion implantation is preferably used to dose amorphous semiconductor material with metal in the process of the invention as it affords precise control over dosage, uniformity and ion depth. Nevertheless, other methods may be employed for this purpose. For example, the metal atoms may be applied to the amorphous semiconductor material in a solution, typically by a spin-coating process. Other processes include sputtering or sol-gel coating a layer of nickel, and the use of a nickel precursor during the amorphous semiconductor material CVD process.

As noted above, the process for forming MIC poly-Si described herein may enable the duration of the annealing step of such a process to be significantly reduced. The inventors have further realised that the reduction in the thermal budget of this step may be sufficient to allow the use of the MIC poly-Si in a bottom gated TFT structure. Examples of known bottom gated TFT structures are the back channel etch (BCE) TFT and the etch stop TFT. In particular, in accordance with the present invention, the gate electrode of the bottom gated poly-Si TFT structure may be formed of metal. Previously, it has been found that the use of thermal annealing sufficient to form polycrystalline silicon, even when promoted by addition of suitable metal atoms, or the formation of poly-Si using a laser annealing process led to diffusion of gate metal through the gate dielectric, shorting the underlying gate to the poly-Si.

The ability to form bottom gated poly-Si TFTs reliably (particularly for applications employing low temperature substrates) is of significant commercial value as it enables the mask count of the fabrication process to be reduced relative to a typical top gate poly-Si TFT manufacturing process. Furthermore, the process is more compatible with existing a-Si manufacturing lines, many of which currently produce bottom gated TFT structures, reducing the expense of converting a line to produce poly-Si TFTs. Also, laser annealing may not be required to produce poly-Si of acceptable quality, avoiding the associated costs.

Suitable materials for forming gate electrodes in a bottom gated TFT in accordance with the invention include refractory metals, such as Cr, W, and MoCr, or low resistivity metals such as Au, Ag or Ni which may be more appropriate for larger displays where gate resistance reduction is important. It will be appreciated that the other gate materials may be selected, depending on the thermal budget and other parameters of a given process and device application.

For example, a metal silicide material may be used to form the gate. Suitable metals for forming the silicide include tungsten, molybdenum, nickel and platinum. A separate anneal step may be carried out to react the selected metal with a-Si to form the corresponding silicide. Alternatively, the anneal step performed in forming the MIC poly-Si of the TFT may simultaneously achieve the silicide formation. As noted above, the relatively low thermal budget of this anneal has the advantage of minimising any risk of diffusion of metal into the gate dielectric.

Other materials which may be used to form the gate electrode include doped hydrogenated a-Si, or microcrystalline silicon. Bottom gate poly-Si TFTs having gate electrodes comprising these materials are described in copending United Kingdom Patent Application no. 0210065.9 (our reference PHGB020060), the contents of which are incorporated herein by reference. Furthermore, metal atoms suitable for promoting the crystallisation of silicon may be included in the a-Si or microcrystalline silicon, so that the crystallinity of the gate material is enhanced during the MIC anneal step. Thus, the gate electrode may comprise semiconductor material and metal atoms suitable for promoting the crystallisation thereof.

In a preferred embodiment of the method of manufacturing an electronic device disclosed herein, a TFT is formed with its channel defined in the polycrystalline semiconductor material which has a bottom gate configuration, and the method comprises a BCE step. Relative to the fabrication of a bottom gate BCE a-Si TFT, the BCE step has a more clearly defined end point in accordance with this embodiment. The removal of n+ a-Si in the BCE process exposes poly-Si (rather than intrinsic a-Si), and so an etchant may be chosen which is selective between a-Si and poly-Si to ensure that the etching process ends once the exposed n+ a-Si has been etched away.

Embodiments of the invention will now be described by way of example with reference to the accompanying schematic drawings wherein:

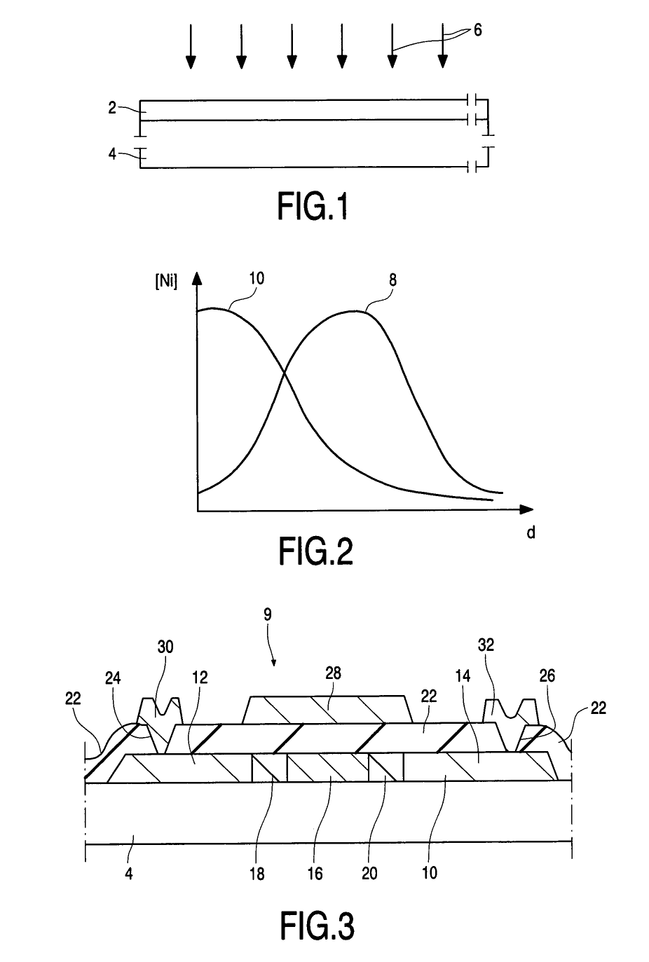

FIG. 1 shows the metal implantation step of a process in accordance with an embodiment of the invention;

FIG. 2 shows the relationship between nickel concentration and depth within a semiconductor film for different doping processes;

FIG. 3 shows a cross-sectional view of a top gate poly-Si TFT formed using a process embodying the invention;

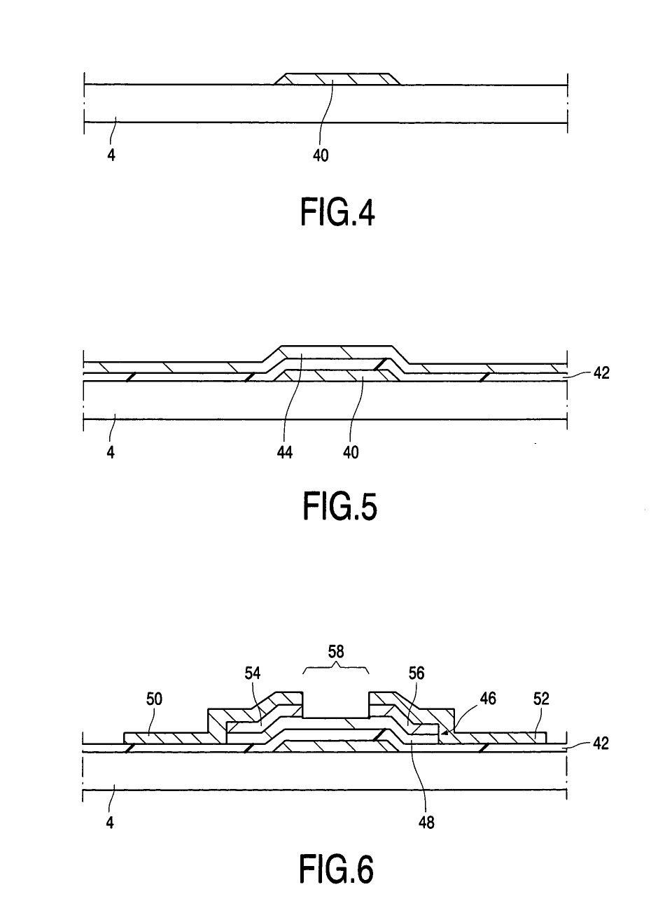

FIGS. 4 to 7 show cross-sectional views of successive stages in the fabrication of a bottom gate TFT according to a further process embodying the invention; and

FIG. 8 shows a perspective view of an active matrix display.

It should be noted that the Figures are diagrammatic and not drawn to scale. Relative dimensions and proportions of parts of these Figures have been shown exaggerated or reduced in size, for the sake of clarity and convenience in the drawings.

A process embodying the invention will be described with reference to FIG. 1. It shows a layer of a-Si 2 which has been deposited on a glass substrate 4. The layer may typically be 40 nm thick and formed using plasma enhanced chemical vapour deposition (PECVD), for example.

An areal density of nickel of around 1×10¹³ atoms/cm² is then implanted into the a-Si layer (this step is represented in FIG. 1 by arrows 6) at an implantation energy typically of 20 keV. Energies of up to 30 keV have been successfully used with layers of this thickness to create TFTs with the desired leakage characteristics. It can be seen that the average concentration of nickel atoms in the 40 nm thick a-Si layer resulting from this dose is therefore around 2.5×10¹⁸ atoms/cm³.

Typical nickel dose profiles in the a-Si layer are illustrated schematically in FIG. 2 for different processes. The depth into the layer increases along the x-axis, with zero representing the upper surface of the layer. Line 8 shows the profile achieved using an implantation process, whilst line 10 shows the profile for a spin-coating, or sputtering process. Implantation results in a peak in the profile occurring within the body of the layer, whereas with the other processes, the highest concentration occurs at the upper surface of the layer. It is thought that this may lead to the formation of better quality crystalline material in comparison with the other doping techniques, as there is a greater concentration of nickel towards the centre of the body of semiconductor material. The use of implantation also facilitates close control of the nickel dosage. The semiconductor material is crystallised by annealing, preferably in N₂ atmosphere, for around 8 hours at 5500C.

Photolithography, implantation, deposition and etching process steps may then be carried out in a known manner to form a poly-Si TFT structure as shown in FIG. 3. The structure shown by way of example in FIG. 3 is a top gate, gate-overlapped lightly doped drain TFT. The semiconductor material is patterned into a poly-Si island 10, comprising doped source and drain regions 12 and 14, an intrinsic channel region 16 and lightly doped regions 18 and 20 therebetween. A layer of insulating material 22 is deposited over the island 10, with vias 24 and 26 defined therein to allow contact to be made with the source and drain regions 12 and 14, respectively by source and drain terminals 30 and 32. A metal gate electrode 28 is provided over the insulating material layer 22.

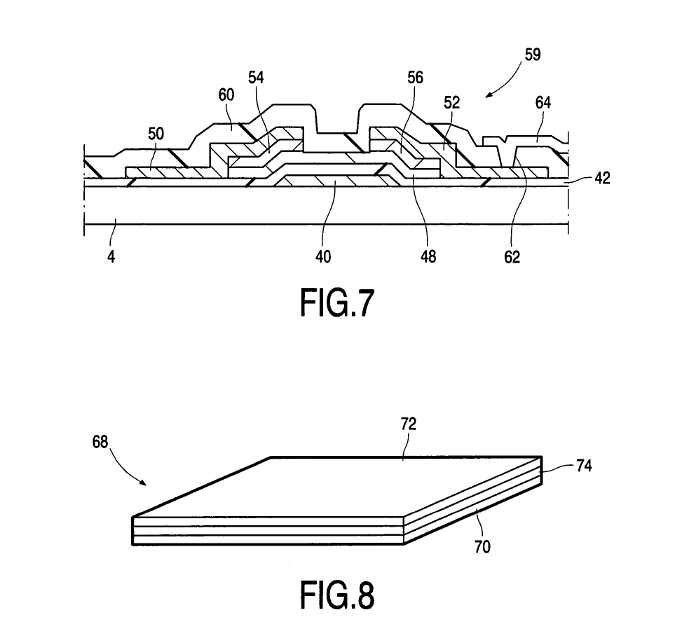

The MIC process described herein enables bottom gated TFTs to be reliably manufactured on low temperature substrates. An example of a process for forming such a device according to the invention will now be described with reference to FIGS. 4 to 7. The finished TFT device shown in FIG. 7 is a BCE TFT. The process only requires 5 mask steps, fewer than a typical poly-Si TFT process, and is therefore relatively cost effective. The employment of each mask is indicated in the process description below in parentheses. Photolithography, implantation, deposition and etching process steps suitable for forming the device are well known in the art and so will not be described in detail.

Firstly, as shown in FIG. 4, a bottom gate 40, of Cr for example, is provided on glass substrate 4 (mask 1). The gate material is selected to be able to withstand the thermal budget of the subsequent MIC anneal and other processing. The relatively low thermal budget of the MIC process disclosed herein enables the use of metals such as Cr.

Gate insulation layer 42 and an a-Si layer 44 are then deposited over the gate 40, as shown in FIG. 5. As described in relation to FIG. 1 above, Ni is then added to the a-Si layer 44, for example by implantation, and then the substrate is annealed, typically for 8 hours at 550° C., converting the a-Si into MIC poly-Si.

A layer of n+ doped a-Si is deposited over the MIC poly-Si and both layers are patterned to form a device island 46 (FIG. 6), comprising MIC poly-Si island 48 and overlying n+ a-Si (mask 2). It may be necessary to clean the MIC poly-Si surface before deposition of the n+ a-Si to ensure a good electrical contact is achieved between the two layers. For example, a thin silicon dioxide layer may form on the MIC poly-Si. A hydrofluoric acid treatment would be a suitable way to remove such an oxide layer.

A layer of metal is then deposited, which is patterned to form source and drain electrodes 50 and 52 (mask 3). A BCE step is now performed, using the source and drain electrodes 50, 52 as a mask defining etch window 58, to remove n+ a-Si material therebetween, exposing the underlying MIC poly-Si and defining n+ a-Si source and drain contact layers 54 and 56.

In known a-Si BCE TFT manufacturing processes, the end point of the BCE step is not clearly defined or controllable as the etching process is not selective between the n+ a-Si and the underlying a-Si. This problem has been addressed by making the a-Si layer thicker and overetching so that some a-Si is removed, to ensure that all the unwanted n+ a-Si is removed. This has the disadvantages of extending the processing time and cost and of making the process less reliably reproducible. However, in the process of FIGS. 4 to 7, etching away of the n+ a-Si exposes MIC poly-Si material and the etchant used in the BCE step may be chosen to be selective between the n+ a-Si and the poly-Si, giving a clearly defined end point to the etching step.

Thus, the present process enables the formation of a BCE TFT with a relatively thin poly-Si region accommodating the channel, rather than a relatively thick a-Si layer. This reduced layer thickness reduces the processing time required to deposit the layer and also serves to reduce leakage in the layer. For example, the channel accommodating a-Si layer of a BCE a-Si TFT is typically around 100 nm thick, whereas the poly-Si layer of the present device may be thinner than this and devices in which this layer is around 40 or even 20 nm thick may be reliably fabricated.

The TFT device is then completed (in the context of an active matrix display device for example) by depositing a passivation layer 60 thereover, opening a contact hole 62 in the passivation layer (mask 4), and depositing and patterning a suitable material (typically indium tin oxide) to form the pixel electrode 64 (mask 5), as illustrated in FIG. 7.

In an alternative approach to that described in relation to FIGS. 5 and 6 above, the n+ a-Si layer may be deposited over the a-Si layer 44 before a MIC process is carried out. The n+ a-Si is then patterned to define source and contact layers 54 and 56, with the channel region of the a-Si exposed therebetween. Metal atoms for promotion of crystallisation of a-Si are then added by one of the methods described herein, for example implantation, and a MIC anneal conducted. In this way, the source and drain contact layers of the n+ a-Si layer are crystallised as well as the channel region of the TFT, thereby improving the conductivity of the source and drain contact layers.

It will be appreciated that in an active matrix display device, an array of TFTs is provided over an active plate for switching respective pixels of the display. As shown in FIG. 8, in a liquid crystal display device 68, an active plate 70 and an opposing passive plate 72 are provided, with liquid crystal material 74 sandwiched therebetween.

It may be particularly advantageous in processes in accordance with the present invention to carry out a plasma hydrogenation process after device fabrication to improve its performance. Typically, this is carried out at around 350° C. for about 1 hour.

TFTs made in accordance with the processes described herein having a channel width of 50 μm have been found to exhibit a leakage current in the off-state of around 8×10⁻¹¹ A at a source-drain voltage of 5V, equivalent to 1.6×10⁻¹² A/μm, and a mobility of around 2 cm²Ns.

The TFT leakage characteristics may be further improved by adopting a fingered channel structure, having 2, 3 or more fingers.

In the embodiment described above with reference to FIGS. 4 to 7, a metal is used to form the gate electrode. However, other materials may be used in accordance with the invention to form the gate electrode.

In other preferred embodiments, the gate electrode comprises a metal silicide. Various approaches may be employed to form such a gate electrode. For example, a layer of a-Si may be deposited and patterned to the desired configuration for the gate electrode. Then a layer of a suitable metal is deposited and an anneal step of suitable temperature and duration is carried out to react the metal with the a-Si, forming the metal silicide. For example, in the case of NiSi₂, the anneal may be performed at 350° C. for about 1 hour.

The metallic material which has not reacted with the a-Si may then be stripped away to leave the gate electrode comprising metal silicide material. Suitable metals include tungsten, molybdenum, nickel and platinum. Other metals may be used, providing that the corresponding silicide formed is able to withstand subsequent processing, notably the MIC anneal step.

The a-Si layer may be around 20-100 nm thick and the silicide forming metal may be provided in a thickness giving the required stochiometric ratio of atoms to react with the a-Si (or greater, with excess metal being stripped away). In a variation on the above metal silicide gate electrode formation process, the metal layer may be deposited on an unpatterned layer of a-Si. The suicide anneal is then performed before patterning the result to form the gate electrode.

In a further variation, the anneal step performed in forming the MIC poly-Si of the TFT may simultaneously achieve the silicide formation, avoiding the need for a separate anneal step to form the silicide. In this approach, an a-Si layer and the silicide forming metal layer are deposited in turn and patterned together to define the gate electrode configuration. They are not then annealed to form the silicide until the MIC anneal step later in fabrication of the device.

Whilst embodiments of the invention are described herein with reference to silicon material (that is, a-Si and poly-Si), it will be apparent that other semiconductor materials, or compound semiconductor films (for example silicon films containing germanium), may be used in accordance with the invention.

It will be appreciated that polycrystalline semiconductor films produced in accordance with the techniques described herein are suitable for use in a wide range of applications in which electronic circuits are formed on substrates which cannot withstand high temperatures such as glass. The films may be used in the formation of active devices such as TFTs, or passive devices (for example resistors, temperature sensors and piezo-resistors) in circuitry on such substrates. TFTs may be employed in AMLCDs, AMPLEDs, X-ray sensors, fingerprint sensors and the like, in the switching matrices of the devices and/or in integrated circuitry on the same substrate as the switching matrices.

The crystalline quality of polycrystalline semiconductor material made using the processes described herein may be further improved by irradiation of the material with an energy beam. As noted above, it may take a significant period of time to scan an energy beam across a substrate. However, as disclosed in copending United Kingdom Patent Application No. 0211724.0 of the present applicants (our reference PHGB020072), the time taken for this may be minimised in the manufacture of active matrix displays by only irradiating the peripheral circuitry integrated on the display substrate around the display area. The contents of United Kingdom Patent Application No. 0211724.0 are incorporated herein by reference.

From reading the present disclosure, other variations and modifications will be apparent to persons skilled in the art. Such variations and modifications may involve equivalent and other features which are already known in the art, and which may be used instead of or in addition to features already described herein.

Although claims have been formulated in this Application to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

The Applicants hereby give notice that new claims may be formulated to such features and/or combinations of such features during the prosecution of the present Application or of any further Application derived therefrom.

1. An electronic device comprising a TFT, the TFT including a channel defined in a layer of polycrystalline semiconductor material produced by crystallising amorphous semiconductor material using metal atoms to promote the crystallisation process, wherein the semiconductor material includes an average concentration of the metal atoms in the range 1.3×10¹⁸ to 7.5×10¹⁸ atoms/cm³.

2. An electronic device of claim 1 wherein the average concentration of the metal atoms in the semiconductor material is around 2.5×10¹⁸ atoms/cm³.

3. An electronic device of claim 1 wherein the TFT has a bottom gate configuration.

4. An electronic device of claim 3 wherein the gate electrode of the TFT comprises a metallic material.

5. An electronic device of claim 1 wherein the gate electrode of the TFT comprises a metal silicide.

6. An electronic device of claim 1 wherein the gate electrode Comprises semiconductor material and metal atoms suitable for promoting the crystallisation thereof.

7. A method of manufacturing an electronic device including the steps of:
(a) depositing amorphous semiconductor material on a substrate;
(b) adding metal atoms to the semiconductor material at an average concentration therein in the range 1.3×10¹⁸ to 4×10¹⁸ atoms/cm³, the metal atoms being suitable for accelerating the crystallisation of amorphous semiconductor material; and
(c) annealing the amorphous semiconductor material to form polycrystalline semiconductor material.

8. A method of claim 7 wherein the metal atoms are added to the amorphous semiconductor material at an average concentration therein of around 2.5×10¹⁸ atoms/cm³.

9. A method of claim 7 or claim 8 wherein the metal atoms are added by implantation.

10. A method of claim 7 wherein the annealing process is carried out for 10 hours or less at a temperature of 600° C. or less, and a TFT is formed with its channel defined in the polycrystalline semiconductor material which exhibits a minimum leakage current of around 2.5×10⁻¹² A/μm or less at a source-drain voltage of 5V.

11. A method of claim 10 wherein the annealing process is carried out for 8 hours or less at a temperature of 550° C. or less, and a TFT is formed with its channel defined in the polycrystalline semiconductor material which exhibits a minimum leakage current of around 2.5×10⁻¹² A/μm or less at a source-drain voltage of 5V.

12. A method of claim 7 wherein a TFT is formed with its channel defined in the polycrystalline semiconductor material which has a bottom gate configuration, the method comprising a back channel etch step.

13. An electronic device of claim 1 or a method of claim 7 wherein the metal atoms comprise nickel atoms.

14. An active matrix display device wherein an electronic device of claim 1 forms the active plate of the active matrix device.
